(19) United States
(12) Patent Application Publication
(10) Pub. No.: US 2024/0414918 A1
(43) Pub. Date: Dec. 12, 2024

(54) SEMICONDUCTOR DEVICE AND MANUFACTURING METHOD OF SEMICONDUCTOR DEVICE

(71) Applicant: SK hynix Inc., Gyeonggi-do (KR)

(72) Inventors: Won Geun CHOI, Gyeonggi-do (KR); Jung Shik JANG, Gyeonggi-do (KR); Rho Gyu KWAK, Gyeonggi-do (KR); Seok Min CHOI, Gyeonggi-do (KR)

(21) Appl. No.: 18/463,296

(22) Filed: Sep. 8, 2023

(30) Foreign Application Priority Data
Jun. 12, 2023 (KR) 10-2023-0074660

(51) Int. Cl. H10B 43/27; H10B 41/27

(52) U.S. Cl. CPC H10B 43/27; H10B 41/27

(57) ABSTRACT

A semiconductor device may include: a gate structure including insulating layers and conductive layers alternately stacked; first supports located in the gate structure, each first support including a second channel layer; second supports located in the gate structure, each second support including a barrier layer; and contact structures extending between the second supports through the gate structure, wherein each contact structure is connected to a corresponding conductive layer.

### CROSS-REFERENCE TO RELATED APPLICATION

This application claims priority under 35 U.S.C. § 119 to Korean Patent Application No. 10-2023-0074660 filed on Jun. 12, 2023, which is incorporated herein by reference in its entirety.

### BACKGROUND

### 1. Technical Field

Embodiments of the present disclosure relate to an electronic device and a manufacturing method of the electronic device, and more particularly, to a semiconductor device and a manufacturing method of the semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, in order to improve the operational reliability of such a semiconductor device, various structures and manufacturing methods have been developed.

### SUMMARY

In an embodiment, a semiconductor device may include: a gate structure including insulating layers and conductive layers alternately stacked; first supports located in the gate structure, each first support including a second channel layer; second supports located in the gate structure, each second support including a barrier layer; and contact structures extending between the second supports through the gate structure, wherein each contact structure is connected to a corresponding conductive layer.

In an embodiment, a manufacturing method of a semiconductor device may include: forming a stack including first material layers and second material layers that are alternately stacked; forming in the stack first supports, each first support including a second channel layer; forming in the stack second supports, each second support including a barrier layer; and forming contact structures between the second supports.

These and other features and advantages of the present invention will become apparent from the following drawings and detailed description of specific embodiments of the present invention.

### BRIEF DESCRIPTION OF THE DRAWINGS

FIG. 1A and FIG. 1B are diagrams for describing a semiconductor device in accordance with an embodiment.

FIG. 2A and FIG. 2B are diagrams for describing a semiconductor device in accordance with an embodiment.

FIG. 3A and FIG. 3B, FIG. 4A and FIG. 4B, FIG. 5A and FIG. 5B, FIG. 6A and FIG. 6B, FIG. 7A and FIG. 7B, FIG. 8A and FIG. 8B, FIG. 9A and FIG. 9B, FIG. 10A and FIG. 10B, FIG. 11A and FIG. 11B, and FIG. 12A and FIG. 12B are diagrams for describing a manufacturing method of a semiconductor device in accordance with an embodiment.

### DETAILED DESCRIPTION

Various embodiments are directed to a semiconductor device having a stable structure and improved characteristics and a manufacturing method of the semiconductor device.

The present technology can provide a semiconductor device having a stable structure and improved reliability.

Hereafter, embodiments in accordance with the scope of the present disclosure will be described with reference to the accompanying drawings.

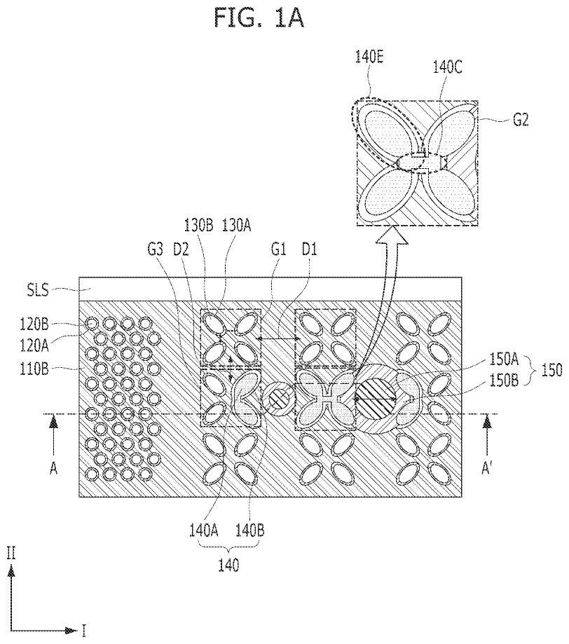

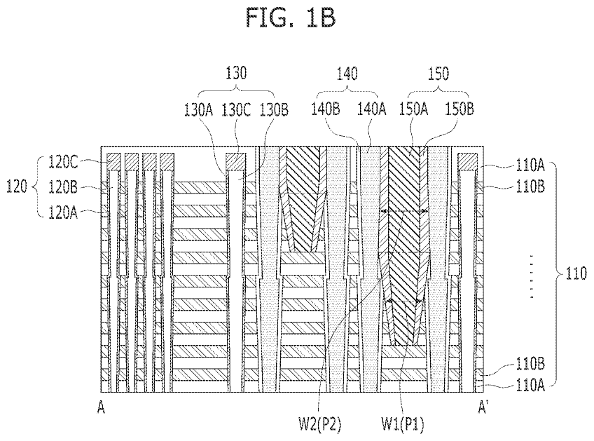

FIG. 1A and FIG. 1B are diagrams for describing a semiconductor device in accordance with an embodiment. FIG. 1A may be a plan view and FIG. 1B may be a cross-sectional view taken along line A-A′ in FIG. 1A.

Referring to FIG. 1A and FIG. 1B, the semiconductor device may include a gate structure 110, channel structures 120, first supports 130, second supports 140, contact plugs 150, or a combination thereof. The semiconductor device may further include a slit structure SLS.

The gate structure 110 may include insulating layers 110A and conductive layers 110B that are alternately stacked. The insulating layers 110A may each include an insulating material, and the conductive layers 110B may each include a conductive material. For example, the insulating layers 110A may each include an insulating material such as an oxide, and the conductive layers 110B may each include a conductive material such as tungsten, molybdenum, or polysilicon.

The channel structures 120 may be located in the gate structure 110. Each of the channel structures 120 may include a first channel layer 120A, a first insulating core 120B, and a first capping layer 120C. For example, each of the channel structures 120 may include a first channel layer 120A, a first insulating core 120B in the first channel layer 120A, and a first capping layer 120C on the first channel layer 120A and the first insulating core layer 120B. Each of the channel structures 120 may further include a first memory layer surrounding the first channel layer 120A.

The slit structure SLS may extend through the gate structure 110. For example, the slit structure SLS may be spaced apart from the channel structures 120, and may extend in a first direction I through the gate structure 110. The slit structure SLS may comprise a slit which can be used as a passage for replacing sacrificial layers with the conductive layers 110B in a manufacturing process. The slit structure SLS may include an insulating material, a conductive material or a semiconductor material.

The first supports 130 may be located in the gate structure 110 and may be dummy channel structures each having a shape similar to that of the channel structures 120. For example, each of the first supports 130 may include a second channel layer 130A, a second insulating core 130B, and a second capping layer 130C. Each of the first supports 130 may include the second channel layer 130A, the second insulating core 130B in the second channel layer 130A, and the second capping layer 130C on the second channel layer 130A. The second channel layer 130A may be a dummy channel layer, the second insulating core 130B may be a dummy insulating core, and the second capping layer 130C may be a dummy capping layer. Each of the first supports 130 may further include a second memory layer surrounding the second channel layer 130A. The second memory layer may be a dummy memory layer.

The first supports 130 may be spaced apart from each other. For example, the first supports 130 may be spaced apart from each other in the first direction I or in a second direction II intersecting the first direction I. Alternatively, the first supports 130 may be spaced apart from each other in a third direction III intersecting the first direction I and the second direction II. The third direction III may mean a diagonal direction between the first direction I and the second direction II in a plane defined by the first direction I and the second direction II.

The first supports 130 may each have an elliptical shape in the plane defined by the first direction I and the second direction II. A long axis of each of the first supports 130 may extend along the third direction III intersecting the first direction I and the second direction II. The first supports 130 adjacent in the first direction I or the second direction II may be arranged so that long axes of the first supports 130 extend in different directions. For example, the first supports 130 adjacent to each other in the first direction I may be arranged so that the long axes of the first supports 130 extend in directions intersecting each other. The first supports 130 adjacent to each other in the second direction II may be arranged so that the long axes of the first supports 130 extend in directions intersecting each other. The long axes of the first supports 130 adjacent in the third direction III may be arranged to be mutually aligned. However, the present disclosure is not limited thereto, and the first supports 130 may include a shape such as a circular shape, an elliptical shape, a polygonal shape, or the like in the plane, or a combination thereof.

The first supports 130 may be simultaneously formed in the process of forming the channel structures 120. Accordingly, the heights of the first supports 130 and the channel structures 120 may be substantially the same. The second channel layer 130A may be located at a level corresponding to the first channel layer 120A, and the second insulating core 130B may be located at a level corresponding to the first insulating core 120B. The second capping layer 130C may be located at a level corresponding to the first capping layer 120C. However, the present disclosure is not limited thereto, and the channel structures 120 and the first supports 130 may also be formed through separate processes. Each of the first supports 130 may include an insulating material instead of the second channel layer 130A, the second insulating core 130B, and the second capping layer 130C.

The second supports 140 may be located in the gate structure 110. Each of the second supports 140 may include a barrier layer 140A or a spacer 140B, or a combination thereof. For example, each of the second supports 140 may include the barrier layer 140A and the spacer 140B surrounding the barrier layer 140A as illustrated in the embodiment of FIGS. 1A and 1B.

Each of the second supports 140 may have an elliptical shape in the plane defined by the first direction I and the second direction II. For example, each of the second supports 140 may include extension portions 140E each having an elliptical shape and connection portions 140C connecting the extension portions 140E. The connection portion 140C may connect extension portions 140E adjacent in the first direction I and/or the second direction II. The extension portions 140E may have in a radial shape expanded from the connection portions 140C. The extension portions 140E may be arranged so that the long axes of the extension portions 140E extend along the third direction III. For example, the extension portions 140E adjacent in the first direction I or the second direction II may be arranged so that the long axes of the extension portions 140E extend in directions intersecting each other. Furthermore, the extension portions 140E adjacent in the third direction III may be arranged so the long axes of the extension portions 140E are mutually aligned. However, the present disclosure is not limited thereto, and the extension portions 140E may include a shape such as a circular shape, an elliptical shape, a polygonal shape, or the like in the plane, or a combination thereof.

The second supports 140 may be used to adjust the sizes of the contact structures 150 in the manufacturing process. For example, by forming the contact structure 150 between the second supports 140 adjacent in the first direction I, an increase in the width of the contact structure 150 may be restricted in the first direction I during the manufacturing process. Furthermore, in the process of forming the contact structures 150, the spacer 140B surrounding the barrier layer 140A may be partially etched. Accordingly, at least a part of the sidewall of the barrier layer 140A may be in contact with at least one of the contact structures 150, and the spacer 140B may surround the remaining sidewall of the barrier layer 140A. The barrier layer 140A may include a material having an etching selectivity with respect to the insulating layers 110A and the conductive layers 110B. The barrier layer 140A may be a single layer or a multilayer. For example, the barrier layer 140A may be a single layer including at least one of titanium nitride (TiN), tungsten (W), poly-silicon (Poly-Si), and aluminum oxide (AlO), or a multilayer including at least one of titanium nitride (TiN), tungsten (W), poly-silicon (Poly-Si), and aluminum oxide (AlO) in combination. The spacer 140B may include an insulating material such as an oxide, for example, silicon dioxide (SiO₂).

The first supports 130 and the second supports 140 may be formed through separate processes. Accordingly, height of the second supports 140 may be different from the height of the first supports 130. For example, the height of the second supports 140 may be greater than the height of the first supports 130.

A first group G1 may include the first supports 130. A second group G2 may include the second support 140. A third group G3 may include a combination of the first supports 130 and the second supports 140. The first group G1 to the third group G3 may be arranged in the first direction I and the second direction II. The first to third groups G1 to G3 may be spaced apart from each other in the first direction by a first distance D1. The first to third groups G1 to G3 may be spaced apart from each other in the second direction by a second distance D2. The first distance D1 and the second distance D2 may be substantially the same or different. For example, the first distance D1 may be greater than the second distance D2. Accordingly, the contact structure 150 may be located between the groups G1 to G3 adjacent in the first direction I. Groups adjacent to the contact structure 150 in the first direction I may be the second group G2 or the third group G3 including the second support 140.

The contact structure 150 may be located between the groups G1 to G3 adjacent in the second direction II. The second distance D2 may be greater than the first distance D1. Groups adjacent to the contact structure 150 in the second direction II may be the second group G2 or the third group G3 including the second support 140.

The contact structures 150 may extend between the second supports 140 through the gate structure 110, and may be connected to the conductive layers 110B, respectively. Each of the contact structures 150 may include a contact plug 150A and an insulating spacer 150B surrounding sidewalls of the contact plug 150A. The contact plug 150A may be in contact with the conductive layer 110B. The contact plug 150A may include a conductive material such as tungsten, and the insulating spacer 150B may include an insulating material such as an oxide or an air gap.

The contact structures 150 may each include a first portion P1 and a second portion P2 located on the first portion P1. The first portion P1 may have a first width W1, and the second portion P2 may have a second width W2. The first width W1 and the second width W2 may be substantially the same or different. For example, the second width W2 may be greater than the first width W1. The widths W1 and W2 may each mean the width of an upper surface, the width of a lower surface, or a width between the upper surface and the lower surface.

In a process of expanding the openings (described below) for forming the contact structures 150, the second supports 140 may be used as etching barriers. Accordingly, the contact structures 150 may be in contact with at least one of the second supports 140. The contact structures 150 may have portions in contact with or separated from the second support 140. For example, each of the contact structures 150 may include the first portion P1 spaced apart from the second support 140 and the second portion P2 in contact with the second support 140. The insulating layers 110A or the conductive layers 110B may be located between the first portion P1 and the second support 140, so that the first portion P1 and the second support 140 may be spaced apart from each other. At least one of the second supports 140 may protrude into the contact structures 150. For example, the barrier layer 140A may protrude into the contact structure 150.

Because the contact structures 150 are formed to be respectively connected to the conductive layers 110B, the heights of the contact structures 150 may be different. For example, there may be a contact structure 150 having a relatively low height and a contact structure 150 having a relatively high height. In a process of forming the contact structure 150 having a relatively high height, the second width W2 of the second portion P2 may increase. The barrier layer 140A of the second supports 140 may restrict an increase in the second width W2.

According to the structure described above, the contact structures 150 may have different heights. Furthermore, the contact structures 150 may be located between the second supports 140, and may restrict an increase in the second width W2 of the second portion P2 in contact with the barrier layer 140A by the barrier layer 140A. Accordingly, when the contact structures 150 having a relatively high height are formed, an excessive increase in the second width W2 of the contact structures 150 may be restricted.

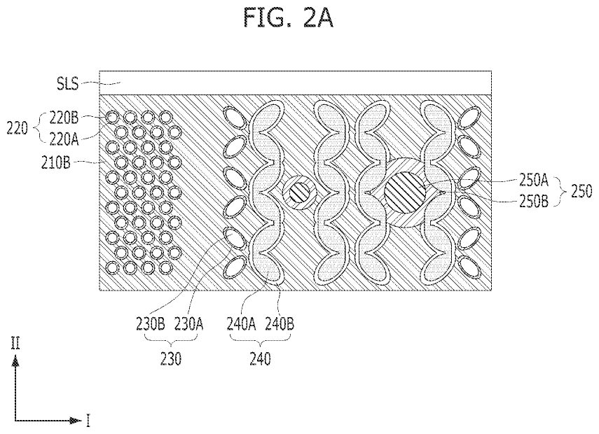

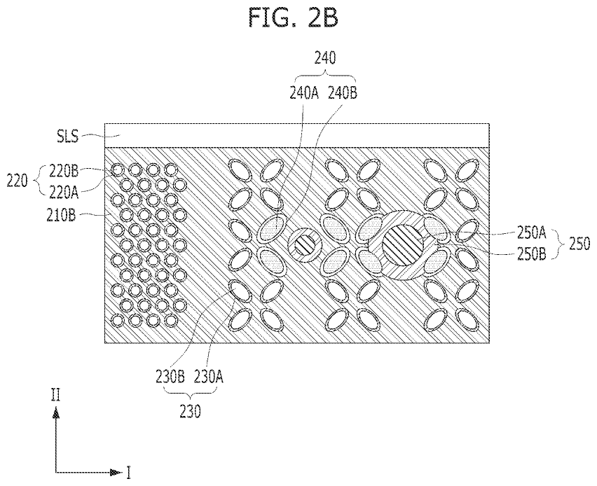

FIG. 2A and FIG. 2B are diagrams for describing a semiconductor device in accordance with an embodiment. FIG. 2A and FIG. 2B may be plan views. Hereinafter, content overlapping with the previously described content may be omitted.

Referring to FIG. 2A and FIG. 2B, a semiconductor device may include a gate structure 210, channel structures 220, first supports 230, second supports 240, contact structures 250, or a combination thereof. The semiconductor device may further include a slit structure SLS.

The gate structure 210 may include insulating layers (corresponding to 110A of FIG. 1B) and conductive layers 210B that are alternately stacked. Each of the channel structures 220 may include a first channel layer 220A and a first insulating core 220B. Each of the channel structures 220 may further include a first capping layer (corresponding to 120C of FIG. 1B) and a first memory layer, or a combination thereof. The first insulating core 220B may be located in the first channel layer 220A. Each of the contact structures 250 may include a contact plug 250A and an insulating spacer 250B. The slit structure SLS may be spaced apart from the channel structures 220, and may extend in the first direction I through the gate structure 210.

Each of the first supports 230 may include a second channel layer 230A and a second insulating core 230B. Each of the first supports 230 may further include a second capping layer (corresponding to 130C of FIG. 1B) and a second memory layer. The second insulating core 230B may be located in the second channel layer 230A. The second channel layer 230A may be a dummy channel layer, the second insulating core 230B may be a dummy insulating core, the second capping layer may be a dummy capping layer, and the second memory layer may be a dummy memory layer. The first supports 230 may be formed when the channel structures 220 are formed. However, the present disclosure is not limited thereto, and the first supports 230 and the channel structures 220 may be formed in separate processes. The first supports 230 may be spaced apart from each other in the first direction I and the second direction II intersecting the first direction I.

Referring now back to FIG. 2A, the contact structures 250 may be located between the second supports 240. The second supports 240 may extend in the second direction II. The second supports 240 may extend in a zigzag shape. The second supports 240 may be spaced apart from each other in the first direction I. A pair of second supports 240 adjacent in the first direction I may have different or identical patterns. For example, the second supports 240 adjacent in the first direction I may each have a zigzag shape repeated at the same cycle. A wide space and a narrow space may be repeatedly defined between the pair of second supports 240, and the contact structures 250 may be located in the wide space. As the contact structure 250 is formed between the second supports 240 adjacent in the first direction I, expansion of the contact structure 250 in the first direction I may be restricted in a manufacturing process.

However, the present disclosure is not limited thereto, and in another embodiment each of the second supports 240 may also have a zigzag shape extending in the first direction I. The contact structure 250 may be formed between the second supports 240 adjacent in the second direction II, and expansion of the contact structure 250 in the second direction II may be restricted in the manufacturing process.

Referring now back to FIG. 2B, the second supports 240 adjacent to the contact structures 250 may be spaced apart from each other in the first direction I and/or the second direction II. For example, in a process of expanding openings for forming the second supports 240, the openings may be expanded but not connected to each other. Accordingly, the second supports 240 may each have a larger size than the first supports 230. The second supports 240 may be arranged to have a radial shape expanded from the center thereof. Furthermore, the second supports 240 adjacent in the first direction I or the second direction II may be arranged so that long axes of the second supports 240 extend in directions intersecting each other. Furthermore, the second supports 240 adjacent in the third direction III intersecting the first direction I and the second direction II may be arranged so that the long axes of the second supports 240 are parallel with each other.

According to the structure described above, the second supports 240 may each have a zigzag shape extending in the second direction II. The contact structure 250 may be located between the second supports 240 adjacent in the first direction I, and expansion of the contact structure 250 in the first direction I may be restricted.

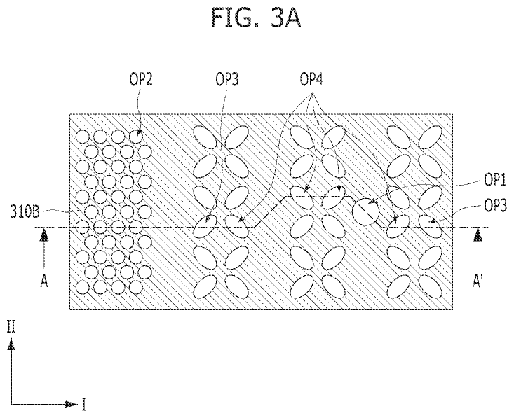

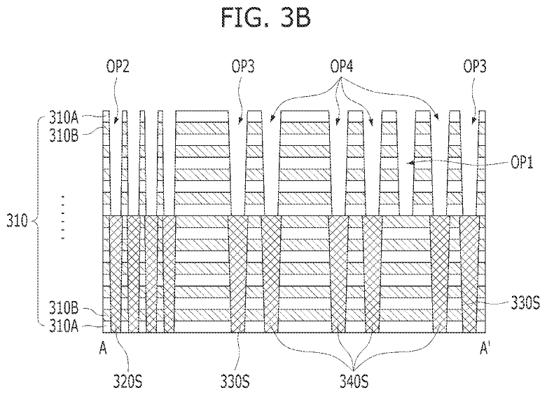

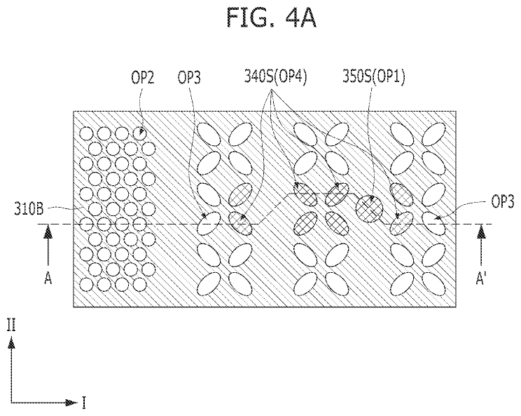

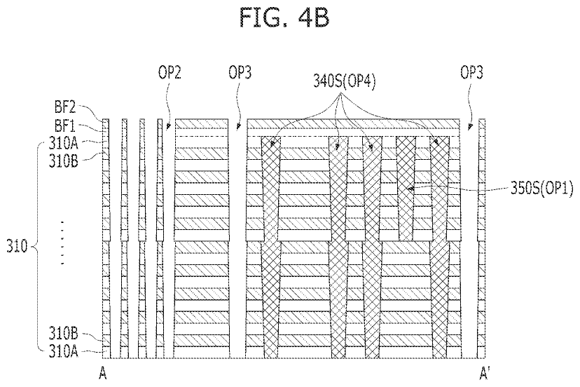

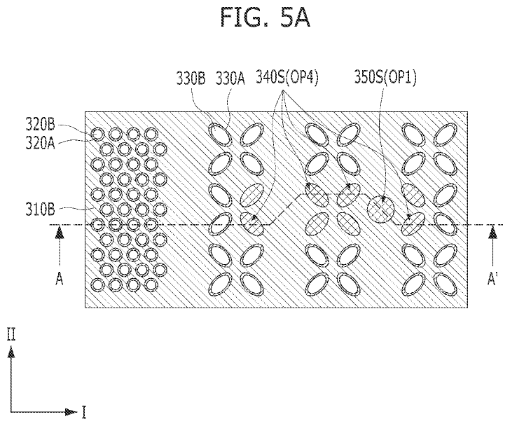

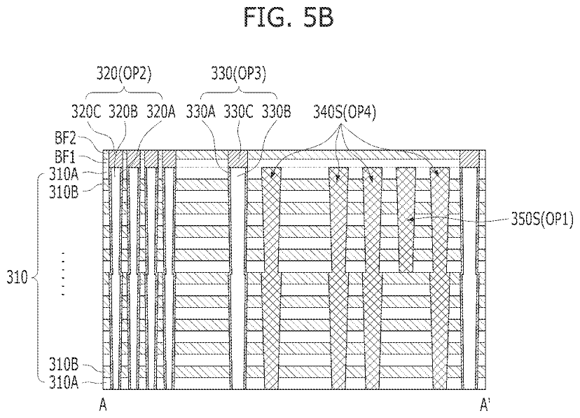

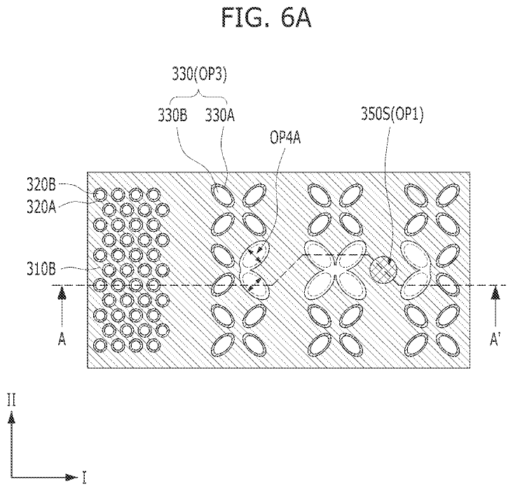

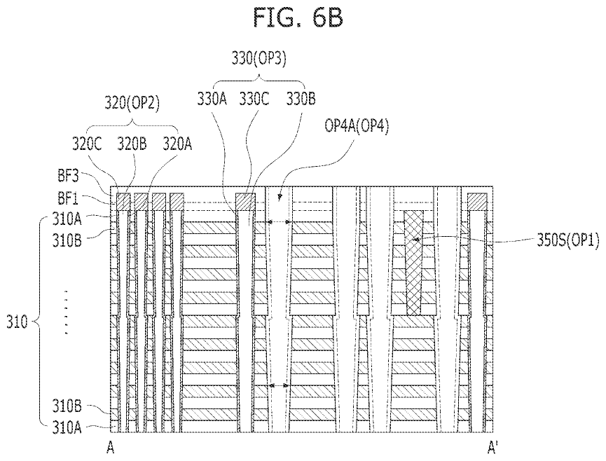

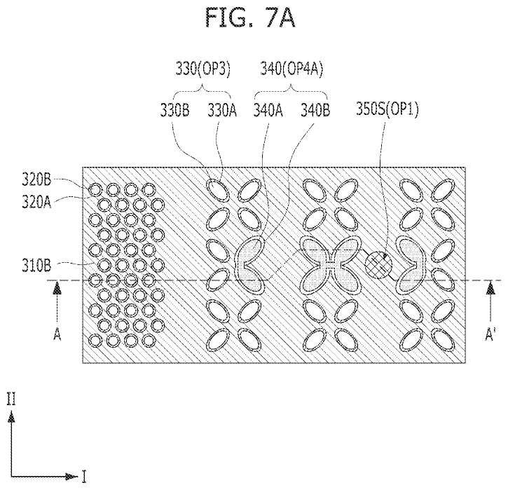

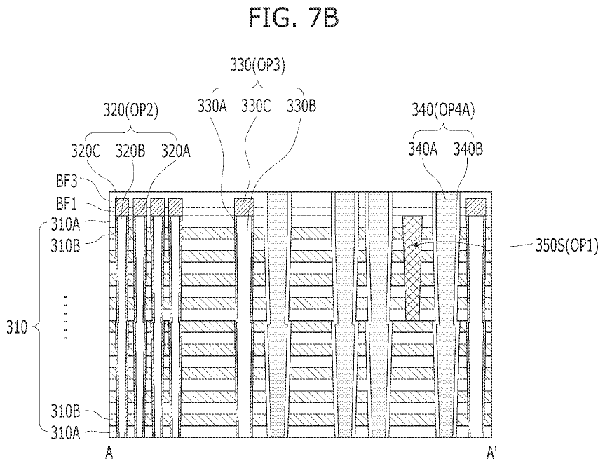

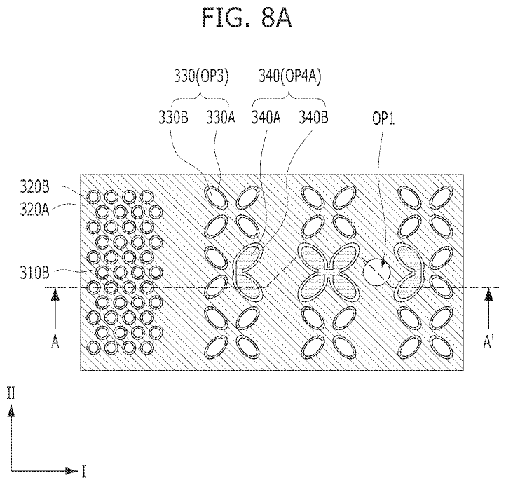

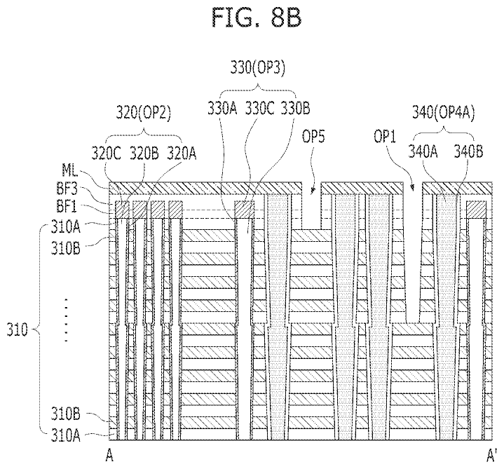

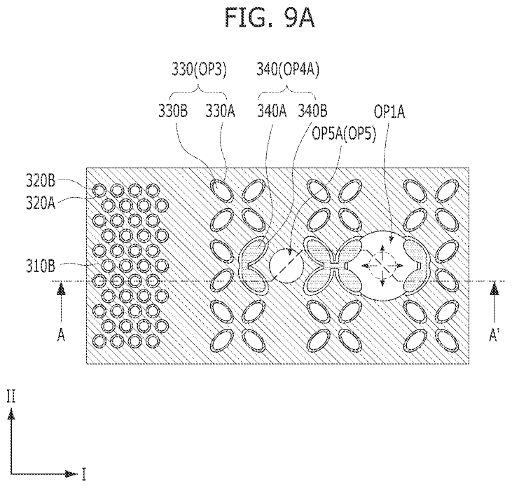

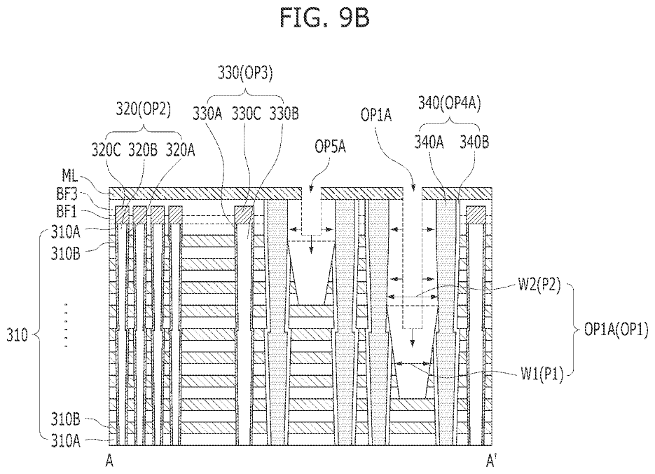

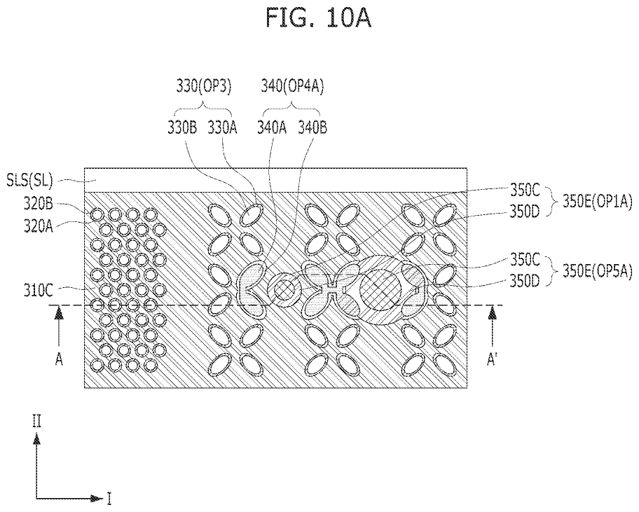

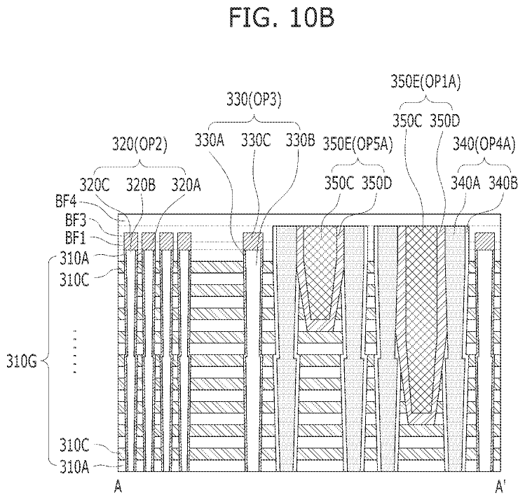

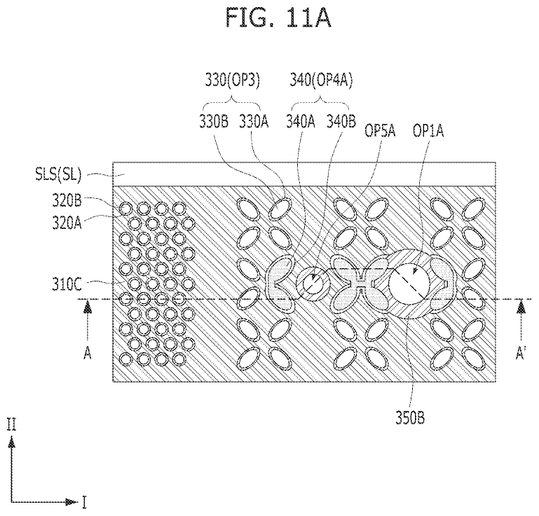

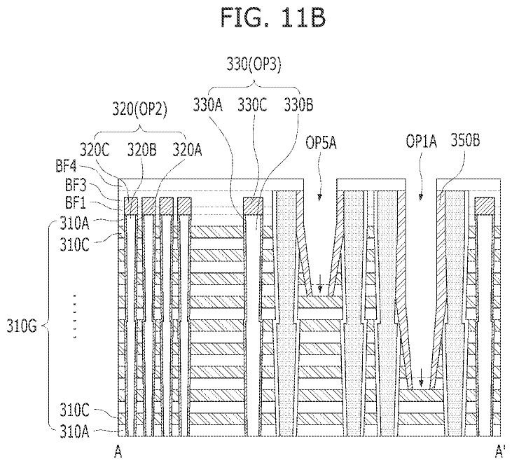

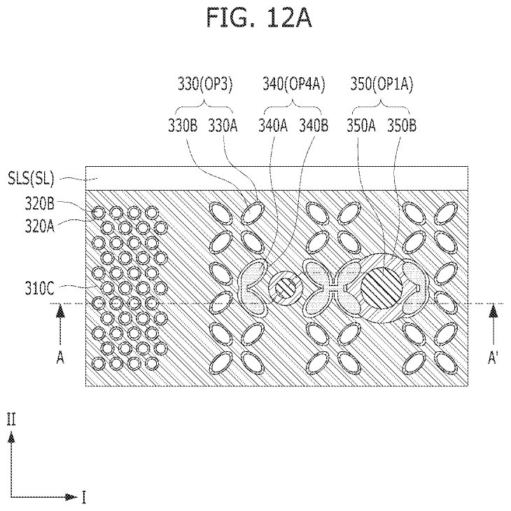

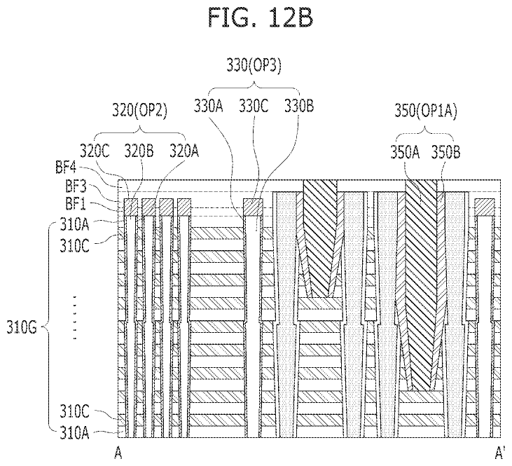

FIG. 3A and FIG. 3B, FIG. 4A and FIG. 4B, FIG. 5A and FIG. 5B, FIG. 6A and FIG. 6B, FIG. 7A and FIG. 7B, FIG. 8A and FIG. 8B, FIG. 9A and FIG. 9B, FIG. 10A and FIG. 10B, FIG. 11A and FIG. 11B, and FIG. 12A and FIG. 12B are diagrams for describing a manufacturing method of a semiconductor device in accordance with an embodiment. FIG. 3A, FIG. 4A, FIG. 5A, FIG. 6A, FIG. 7A, FIG. 8A, FIG. 9A, FIG. 10A, FIG. 11A, and FIG. 12A may be plan views, and FIG. 3B, FIG. 4B, FIG. 5B, FIG. 6B, FIG. 7B, FIG. 8B, FIG. 9B, FIG. 10B, FIG. 11B, and FIG. 12B may be cross-sectional views taken along line A-A′ in FIG. 3A, FIG. 4A, FIG. 5A, FIG. 6A, FIG. 7A, FIG. 8A, FIG. 9A, FIG. 10A, FIG. 11A, and FIG. 12A, respectively. Hereinafter, the content overlapping with the previously described content may be omitted.

Referring to FIG. 3A and FIG. 3B, a stack 310 may be formed by alternately stacking first material layers 310A and second material layers 310B. The first material layers 310A may each include an insulating material such as oxide, and the second material layers 310B may each include a sacrificial material such as nitride or a conductive material such as polysilicon or molybdenum.

Second openings OP2 may be formed in the stack 310. The stack 310 may be divided into a lower stack and an upper stack. Before the upper stack is formed, second sacrificial layers 320S may be formed in the lower stack. The second sacrificial layer 320S may include a sacrificial material such as tungsten or carbon. Subsequently, the stack 310 may be formed by forming the upper stack. Subsequently, the second openings OP2 exposing the second sacrificial layers 320S through the upper stack may be formed. The second sacrificial layers 320S and the second openings OP2 may be used to form channel structures. The second openings OP2 may each have a circular shape in the plane defined by the first direction I and the second direction II intersecting the first direction I. However, the present disclosure is not limited thereto, and the second openings OP2 may each have a shape including a circular shape, an elliptical shape, or a polygonal shape, or a combination thereof.

Third openings OP3 may be formed in the stack 310. For example, third sacrificial layers 330S may be formed in the lower stack. The third sacrificial layer 330S may include a sacrificial material such as tungsten or carbon. Subsequently, after the upper stack is formed, the third openings OP3 exposing the third sacrificial layers 330S through the upper stack may be formed. The third sacrificial layers 330S and the third openings OP3 may be used to form first supports. The third openings OP3 may each have an elliptical shape in the plane. However, the present disclosure is not limited thereto, and the third openings OP3 may each have a shape including a circular shape, an elliptical shape, or a polygonal shape, or a combination thereof.

The third openings OP3 may be spaced apart from each other in the first direction I and/or the second direction II. When the third openings OP3 each have an elliptical shape in the plane, long axes of the third openings OP3 may extend along the third direction III intersecting the first direction I and the second direction II. The third direction III may mean a diagonal direction between the first direction I and the second direction II in the plane defined by the first direction I and the second direction II. The long axes of the third openings OP3 adjacent in the first direction I or the second direction II may extend in directions intersecting each other. The third openings OP3 may each have a radial shape expanded from the center thereof.

A cross-sectional area of each of the third openings OP3 may be substantially the same as or different from a cross-sectional area of each of the second openings OP2. For example, the cross-sectional area of each of the third openings OP3 may be greater than that of each of the second openings OP2. When the second openings OP2 are formed, the third openings OP3 may be formed. However, the present disclosure is not limited thereto, and the third openings OP3 may be formed at a different time than the second openings OP2.

Fourth openings OP4 may be formed in the stack 310. Initially, fourth sacrificial layers 340S may be formed in the lower stack. The fourth sacrificial layer 340S may each include a sacrificial material such as tungsten or carbon. Subsequently, after the upper stack is formed, the fourth openings OP4 exposing the fourth sacrificial layers 340S through the upper stack may be formed. The fourth sacrificial layers 340S and the fourth openings OP4 may be used to form second supports. The fourth openings OP4 may each have an elliptical shape in the plane. However, the present disclosure is not limited thereto, and the fourth openings OP4 may each have a circular shape, an elliptical shape, or a polygonal shape, or a combination thereof.

The fourth openings OP4 may be spaced apart from each other in the first direction I and/or the second direction II. When the fourth openings OP4 each have an elliptical shape in the plane, the long axes of the fourth openings OP4 may extend along the third direction III. The fourth openings OP4 adjacent in the first direction I or the second direction II may be formed so that long axes of the fourth openings OP4 extend in directions intersecting each other. The fourth openings OP4 may have a radial shape expanded from the center thereof.

A cross-sectional area of each of the fourth openings OP4 may be substantially the same as or different from a cross-sectional area of each of the second openings OP2 or each of the third openings OP3. For example, the cross-sectional area of each of the fourth openings OP4 may be greater than that of each of the second openings OP2, and may be substantially equal to that of each of the third openings OP3. The second openings OP2 and the fourth openings OP4 may be formed at the same time. The third openings OP3 and the fourth openings OP4 may be formed at the same time. For example, when the second openings OP2 or the third openings OP3 are formed, the fourth openings OP4 may be formed. However, the present disclosure is not limited thereto, and the fourth openings OP4 may be formed at a different time from the second openings OP2 or the third openings OP3.

A first opening OP1 may be formed in the stack 310. For example, the first opening OP1 may be formed in the upper stack. The first opening OP1 may be used to form contact structures in a subsequent process. For example, the first opening OP1 may be used to form a contact structure having a relatively high height among the contact structures. The first opening OP1 may be formed between the fourth openings OP4. The height of the first opening OP1 may be lower than the heights of the openings OP2, OP3, and OP4. For example, the height of the first opening OP1 may be a height by which only a part of the stack 310 is penetrated.

A sub-stack may also be additionally formed. For example, the sub-stack may also be additionally formed on the stack 310. Before the sub-stack is formed, a sacrificial material may be formed in the openings OP1 to OP4 formed in the upper stack of the stack 310. A plurality of first openings OP1 may be formed. The plurality of first openings OP1 may be formed at substantially the same level, and may be formed as many as the number of second material layers 310B included in the lower stack. The plurality of first openings OP1 may be used to form contact structures having different heights.

Referring to FIG. 4A and FIG. 4B, at least one of the second openings OP2 and the third openings OP3 may be reopened. First, by forming sacrificial materials in the openings OP1 to OP4, the sacrificial layers 320S, 330S, 340S, and 350S may be formed. Subsequently, a first buffer layer BF1 may be formed on the stack 310. Subsequently, a second buffer layer BF2 may be formed on the first buffer layer BF1. The first buffer layer BF1 may include an insulating material such as oxide, and the second buffer layer BF2 may include an insulating material such as nitride. Subsequently, the sacrificial layers 320S and 330S may be exposed by etching the second buffer layer BF2 and the first buffer layer BF1, and then the openings OP2 and OP3 may be reopened by removing the sacrificial layers 320S and 330S. The first sacrificial layer 350S and the fourth sacrificial layers 340S may remain.

Referring to FIG. 5A and FIG. 5B, channel structures 320 may be formed. First, a first channel layer 320A may be formed in each of the second openings OP2. Subsequently, a first insulating core 320B may be formed in the first channel layer 320A. Subsequently, a first capping layer 320C may be formed on the first insulating core 320B and the first channel layer 320A. A first memory layer may be formed in each of the second openings OP2 before the first channel layer 320A is formed.

First supports 330 each including a second channel layer 330A may be formed in the stack 310. First, a second channel layer 330A may be formed in the third openings OP3. Subsequently, a second insulating core 330B may be formed in the second channel layer 330A. Subsequently, a second capping layer 330C may be formed on the second channel layer 330A. A second memory layer may be formed in each of the third openings OP2 before the second channel layer 330A is formed. The second channel layer 330A may be a dummy channel layer, the second insulating core 330B may be a dummy insulating core, the second capping layer 330C may be a dummy capping layer, and the second memory layer may be a dummy memory layer.

When the channel structures 320 are formed, the first supports 330 may be formed. For example, when the first channel layer 320A is formed, the second channel layer 330A may be formed. Alternatively, when the first insulating core 320B is formed, the second insulating core 330B may be formed. Alternatively, when the first capping layer 320C is formed, the second capping layer 330C may be formed.

The first supports 330 may also be formed at a different time from the channel structures 320. Each of the first supports 330 may include an insulating material such as oxide instead of the second channel layer 330A, the second insulating core 330B, and the second capping layer 330C.

Referring to FIG. 6A and FIG. 6B, expanded fourth openings OP4A may be formed by expanding the fourth openings OP4. First, the second buffer layer BF2 may be removed, and a third buffer layer BF3 may be formed on the first buffer layer BF1. The third buffer layer BF3 may cover the channel structures 320 and the first supports 330. The third buffer layer BF3 may include an insulating material such as an oxide. Subsequently, the third buffer layer BF3 may be etched to expose the fourth sacrificial layers 340S, and then the fourth openings OP4 may be reopened by removing the fourth sacrificial layers 340S. Subsequently, the first material layers 310A and the second material layers 310B exposed through the fourth openings OP4 may be etched to form the expanded fourth openings OP4A. During the formation of the fourth openings OP4A, the fourth openings OP4 adjacent to each other may be connected to each other. For example, the fourth openings OP4A may each have a shape in which the fourth openings OP4 adjacent to each other in the first direction I and/or the second direction II are connected to each other. During the formation of the fourth openings OP4A, the channel structures 320 and the first supports 330 are not exposed by the third buffer layer BF3 and thus might not be damaged.

The shapes of the fourth openings OP4A may vary depending on a distance between the fourth openings OP4, the shapes of the fourth openings OP4A, and the degree of expansion of the fourth openings OP4A. For example, when a distance between the fourth openings OP4 adjacent to each other in the second direction II is shorter than a distance between the fourth openings OP4 adjacent to each other in the first direction I, the fourth openings OP4A may have shapes extending in the second direction II. When the fourth openings OP4 each have an elliptical shape in the plane, long axes of the fourth openings OP4 adjacent in the second direction II may extend in the third direction III where the first and second directions I and II intersect each other. The fourth openings OP4A may each have an elliptical shape having long axes extending in the third direction III and intersecting each other. When the distance between the fourth openings OP4 is sufficient in the first direction I and the second direction II, even though the fourth openings OP4 are expanded, the fourth openings OP4 might not be connected to each other, and the fourth openings OP4A may be formed while maintaining the shape of the fourth openings OP4.

Referring to FIG. 7A and FIG. 7B, second supports 340 each including a barrier layer 340A may be formed in the stack 310. First, a spacer 340B may be formed in each of the expanded fourth openings OP4A. Subsequently, the barrier layer 340A may be formed in the spacer 340B. Thus, the second supports 340 each including the barrier layer 340A and the spacer 340B surrounding the barrier layer 340A may be formed. The barrier layer 340A may be formed as a single layer or a multilayer. For example, the barrier layer 340A may be a single layer including at least one of tungsten nitride (TIN), tungsten (W), poly-silicon (Poly-Si), and aluminum oxide (Al), or a multilayer including at least one of tungsten nitride (TiN), tungsten (W), poly-silicon (Poly-Si), and aluminum oxide (AI), or a combination thereof.

The second supports 340 may restrict an excessive increase in the widths of openings (OP1 and the like) for forming contact structures in a subsequent process. The barrier layer 340A may have an etching selectivity with respect to the first material layers 310A and the second material layers 310B. Accordingly, the second supports 340 may be used as etching barriers when the openings OP1 and the like are expanded. The barrier layer 340A may restrict an excessive increase in the widths of the openings OP1 and the like by restricting the range in which the material layers 310A and 310B are etched when the openings OP1 and the like are expanded.

Referring to FIG. 8A and FIG. 8B, the first opening OP1 may be reopened. First, a mask layer ML may be formed on the third buffer layer BF3. The mask layer ML may include polysilicon, a hard mask, and the like. Subsequently, the mask layer ML, the third buffer layer BF3, and the first buffer layer BF1 may be etched to expose the first sacrificial layer 350S, and then the first sacrificial layer 350S may be removed to reopen the first opening OP1.

A fifth opening OP5 may be formed between the second supports 340. The fifth opening OP5 may be used to form a contact structure. The first opening OP1 and the fifth opening OP5 may be used to form contact structures having different heights. The fifth opening OP5 may be used to form a contact structure having a height lower than that of the first opening OP1.

When the first sacrificial layer 350S is exposed, the fifth opening OP5 may be formed. For example, when an opening for exposing the first sacrificial layer 350S is formed, the fifth opening OP5 exposing at least one of the second material layers 310B may be formed by etching the mask layer ML, the third buffer layer BF3, and the first buffer layer BF1.

Referring to FIG. 9A and FIG. 9B, an expanded first opening OP1A may be formed by expanding the first opening OP1. An expanded fifth opening OP5A may be formed by expanding the fifth opening OP5. When the first opening OP1A is formed, the second supports 340 may be exposed. For example, when the first opening OP1 is expanded, the second supports 340 used as etching barriers may be exposed. Some sidewalls of the second support 340 may be exposed by the first opening OP1A, and the remaining sidewalls of the second support 340 might not be exposed by the first opening OP1A. At this time, a part of the second support 340 may be etched. For example, the spacers 340B of the second supports 340 may be etched, and the barrier layer 340A may be exposed. Because the barrier layer 340A may include a material having an etching selectivity with respect to the first material layers 310A and the second material layers 310B, the second supports 340 may be used as an etching barrier when the first opening OP1 is expanded. An excessive increase in the width of the first opening OP1A may be restricted by the barrier layer 340A.

When the first opening OP1 is expanded, because an upper portion of the first opening OP1 may be more exposed to an etching environment than a lower portion thereof, the upper portion may have a greater width than the lower portion. Accordingly, the first opening OP1A may have a first portion P1 having a relatively small width and a second portion P2 having a relatively large width. The first opening OP1A may include the first portion P1 spaced apart from the second support 340 and the second portion P2 exposing the barrier layer 340A. The first material layers 310A and the second material layers 310B may remain between the first portion P1 and the second support 340. The first portion P1 may have a first width W1. The second portion P2 may have a width substantially equal to or different from that of the first portion P1. For example, the second portion P2 may have a second width W2 greater than the first width W1. The widths W1 and W2 may mean the width of an upper surface, the width of a lower surface, or a width between the upper surface and the lower surface.

When the expanded fifth opening OP5A is formed, the second supports 340 may also be exposed and may be used as etching barriers. The fifth opening OP5A may also have a first portion spaced apart from the second support 340 and a second portion in contact with the second support 340. Accordingly, an excessive increase in the width of the second portion of the fifth opening OP5A may be restricted by the second supports 340.

A plurality of first openings OP1 and a plurality of fifth openings OP5 may be formed at locations where contact structures are to be formed. The plurality of first openings OP1 and the plurality of fifth openings OP5 may extend to different heights. For example, a mask pattern exposing at least one of the plurality of first openings OP1 and at least one of the plurality of fifth openings OP5 may be formed. Subsequently, the stack 310 may be etched using the mask pattern as an etching barrier. Subsequently, the stack 310 may be etched by increasing the number of the first openings OP1 and the fifth openings OP5 exposed by reducing the mask pattern. As described above, by repeatedly performing the process of reducing the mask pattern and etching the stack 310, the plurality of first openings OP1 and the plurality of fifth openings OP5 may extend to different heights.

Referring to FIG. 10A and FIG. 10B, preliminary contact structures 350E may be formed. First, the mask layer ML may be removed. Subsequently, a preliminary insulating spacer 350D may be formed in the first opening OP1A and the fifth opening OP5A. Subsequently, a fifth sacrificial layer 350C may be formed in the preliminary insulating spacer 350D. Thus, the preliminary contact structures 350E each including the preliminary insulating spacer 350D and the fifth sacrificial layer 350C may be formed. The fifth sacrificial layer 350C may include a sacrificial material such as tungsten. Subsequently, a fourth buffer layer BF4 may be formed on the third buffer layer BF3. The fourth buffer layer BF4 may be formed to cover the second supports 340 and the preliminary contact structures 350E. The fourth buffer layer BF4 may include an insulating material such as oxide.

A slit structure SLS may be formed. First, a slit SL extending in the first direction I through the stack 310 may be formed. Subsequently, the second material layers 310B may be replaced with third material layers 310C through the slit SL. Through this, a gate structure 310G including the first material layers 310A and the third material layers 310C that are alternately stacked may be formed. The third material layers 310C may each include a conductive material such as tungsten or molybdenum. When the second material layers 310B each include a conductive material, the replacement process may be omitted. In such a case, the second material layers 310B may be used as the third material layers 310C, and the stack 310 may be used as the gate structure 310G. Subsequently, the slit structure SLS may be formed in the slit SL. The slit structure SLS may include an insulating layer or a source contact structure connected to the source structure.

Referring to FIG. 11A and FIG. 11B, the first opening OP1A and the fifth opening OP5A may be reopened. First, a mask layer may be formed, the fifth sacrificial layer 350C may be exposed through the mask layer, and then the fifth sacrificial layer 350C may be removed to reopen the first opening OP1A and the fifth opening OP5A.

Subsequently, lower surfaces of the preliminary insulating spacer 350D exposed through the first opening OP1A and the fifth opening OP5A may be etched to expose the third material layers 310C. A remaining portion of the preliminary insulating spacer 350D may be used as an insulating spacer 350B.

Referring to FIG. 12A and FIG. 12B, contact structures 350 may be formed. A contact plug 350A may be formed in the insulating spacer 350B. In other words, the contact plug 350A may be formed in each of the reopened first opening OP1A and the reopened fifth opening OP5A. Thus, the contact structure 350 including the contact plug 350A and the insulating spacer 350B surrounding the contact plug 350A may be formed. The contact plug 350A may be electrically connected to at least one of the third material layers 310C of the gate structure 310G.

According to the manufacturing method described above, when the first opening OP1 and/or the fifth opening OP5 are expanded, the widths of the expanded openings OP1A and OP5A may be restricted by the second supports 340. For example, when the openings OP1 and OP5 are expanded, the expansion range may be restricted by the material layers 310A and 310B and the second supports 340 having an etching selectivity, so that an excessive extension of the widths of the openings OP1A and OP5A may be restricted.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of the present disclosure.

What is claimed is:

1. A semiconductor device comprising:
a gate structure including insulating layers and conductive layers alternately stacked;
first supports located in the gate structure, each first support including a second channel layer;
second supports located in the gate structure, each second support including a barrier layer; and
contact structures extending between the second supports through the gate structure, wherein each contact structure is connected to a corresponding conductive layer.

2. The semiconductor device of claim 1, wherein each contact structure comprises first portion having a first width and second portion having a second width, respectively, wherein the first portion is spaced apart from the second support whereas the second portion is in contact with the second support.

3. The semiconductor device of claim 2, the second width is greater than the first width.

4. The semiconductor device of claim 1, wherein the contact structures are in contact with at least one of the second supports, and the at least one second support protrudes into the contact structures.

5. The semiconductor device of claim 1, wherein each of the contact structures comprises:
a contact plug; and
an insulating spacer surrounding sidewalls of the contact plug.

6. The semiconductor device of claim 1, wherein each of the second supports comprises:
a barrier layer extending through the gate structure, wherein at least a part of a sidewall of the barrier layer is in contact with at least one of the contact structures; and
a spacer surrounding a remaining sidewall of the barrier layer.

7. The semiconductor device of claim 6, wherein the barrier layer protrudes into the at least one contact structure.

8. The semiconductor device of claim 6, wherein the barrier layer includes a material having an etching selectivity with respect to the insulating layers and the conductive layers.

9. The semiconductor device of claim 6, wherein the barrier layer includes at least one of titanium nitride and tungsten.

10. The semiconductor device of claim 1, wherein each first support has an elliptical shape in a plane defined by a first direction and a second direction intersecting the first direction.

11. The semiconductor device of claim 10, wherein long axes of the first supports extend along a third direction intersecting the first direction and the second direction in the plane defined by the first direction and the second direction.

12. The semiconductor device of claim 10, wherein the first supports adjacent in the first direction or the second direction are arranged so that long axes of the first supports extend in directions intersecting each other.

13. The semiconductor device of claim 10, wherein the first supports are arranged to have a radial shape extending from a center thereof.

14. The semiconductor device of claim 1, wherein, in a plane defined by a first direction and a second direction intersecting the first direction, each of the second supports comprises:
extension portions each having an elliptical shape; and
connection portions connecting the extension portions.

15. The semiconductor device of claim 14, wherein the extension portions have a radial shape expanded from the connection portions.

16. The semiconductor device of claim 1, further comprising:
channel structures extending through the gate structure, each channel structure including a first channel layer.
